(19) United States
(12) Patent Application Publication
(10) Pub. No.: US 2025/0160058 A1
(43) Pub. Date: May 15, 2025

(54) SEMICONDUCTOR LIGHT-EMITTING ELEMENT

(71) Applicant: QuantumZ Inc., KAOHSIUNG CITY (TW)

(72) Inventors: CHUNG-YU HONG, KAOHSIUNG CITY (TW); CHUN-CHIEH CHEN, KAOHSIUNG CITY (TW); CHUN-I WU, KAOHSIUNG CITY (TW); LONG-YI LIN, KAOHSIUNG CITY (TW); MING-CHE HSIEH, KAOHSIUNG CITY (TW)

(21) Appl. No.: 18/899,442

(22) Filed: Sep. 27, 2024

(30) Foreign Application Priority Data
Nov. 10, 2023 (TW) 112143339

(51) Int. Cl. H01L 33/10; H01L 33/30

(52) U.S. Cl. CPC H10H 20/814; H10H 20/8242

(57) ABSTRACT

A semiconductor light-emitting element is provided, including: a substrate, a first distributed Bragg reflector (DBR), an active layer, a second DBR, a first contact layer, a second contact layer, a first metal layer and a second metal layer. The first contact layer, the first DBR, the active layer, the second DBR and the second contact layer are stacked layer by layer in a thickness direction to form a columnar structure. The semiconductor light-emitting element further includes an insulating layer at least partially covered on an outer surface of the columnar structure, and the insulating layer defines an embedding groove open in the thickness direction. A connecting portion of the second metal layer is embedded within the embedding groove and connected with the second contact layer.

### BACKGROUND OF THE INVENTION

### Field of the Invention

The present invention relates to a semiconductor light-emitting element.

### Description of the Prior Art

Generally, a vertical cavity surface emitting laser (VCSEL) includes an active layer, two distributed Bragg reflectors (DBRs) located at two opposite sides of the active layer and an oxide layer adjacent to the active layer. The active layer generates photons, and the photons are trapped and reflected back and forth several times between the two DBRs and then emitted from a top of the VCSEL. The VCSEL has advantages of easy manufacturing, low cost, small divergence angle and high coupling efficiency.

To control the modes and polarization of the VCSEL, the oxide layer is formed with an oxide aperture, and a diametrical dimension of the oxide aperture may be changed to suppress side-modes so as to reduce the modes of the VCSEL and stabilize the polarization of the VCSEL. In some cases, a size of a light emitting hole of the VCSEL may be modulated, or a surface grating or a surface etch may be provided on the VCSEL for the purposes as mentioned above. However, the method of decreasing the oxide aperture has poor reliability and may lead to problems such as reduced light output power, increased resistance of the active layer, increased thermal effects. The methods of changing the size of the light emitting hole and providing the surface grating or the surface etch require complex processing, which may result in reduced production yield and poor optical output efficiency.

The present invention is, therefore, arisen to obviate or at least mitigate the above-mentioned disadvantages.

### SUMMARY OF THE INVENTION

The main object of the present invention is to provide a semiconductor light-emitting element, which has order modes and stable polarization.

To achieve the above and other objects, the present invention provides a semiconductor light-emitting element, including: a substrate, a first DBR, an active layer, a second DBR, a first contact layer, a second contact layer, a first metal layer and a second metal layer. The substrate defines a thickness direction. The first DBR is disposed on a side of the substrate in the thickness direction and includes a plurality of distributed Bragg reflector (DBR) pairs. The active layer is disposed on a side of the first DBR opposite to the substrate. The second DBR is disposed on a side of the active layer opposite to the first DBR in the thickness direction, and the second DBR includes a plurality of DBR pairs. A reflectivity of the second DBR is greater than a reflectivity of the first DBR. The first contact layer is disposed between the substrate and the first DBR. The second contact layer is disposed on a side of the second DBR opposite to the active layer in the thickness direction. The first metal layer is electrically connected with the first contact layer. The second metal layer is electrically connected with the second contact layer. A light emitting side of the semiconductor light-emitting element is located at a side of the substrate remote from the first DBR. The first contact layer, the first DBR, the active layer, the second DBR and the second contact layer are stacked layer by layer in the thickness direction to form a columnar structure, and the columnar structure defines a central axis. The semiconductor light-emitting element further includes an insulating layer at least partially covered on an outer surface of the columnar structure. The insulating layer defines an embedding groove open in the thickness direction, and a connecting portion of the second metal layer is embedded within the embedding groove and connected with the second contact layer. The second DBR further includes a metal diffusion layer, the metal diffusion layer is located at a side of at least one of the second contact layer and the plurality of pairs of semiconductor layers close to the second metal layer, and the metal diffusion layer extends and diffuses in a direction remote from the second metal layer.

The present invention will become more obvious from the following description when taken in connection with the accompanying drawings, which show, for purpose of illustrations only, the preferred embodiment(s) in accordance with the present invention.

### BRIEF DESCRIPTION OF THE DRAWINGS

FIG. 1 is a cross-sectional view of a first preferable embodiment of the present invention;

FIG. 2 is a top view of the first preferable embodiment of the present invention;

FIG. 3 is a diagram showing modeling reflectivities of a second DBR in optical paths with different numbers of pairs of semiconductor layers according to the first preferable embodiment of the present invention;

FIG. 4 is a top view of a second preferable embodiment of the present invention;

FIG. 5 is a top view of a third preferable embodiment of the present invention;

FIG. 6 is a cross-sectional view of a fourth preferable embodiment of the present invention;

FIG. 7 is a top view of the fourth preferable embodiment of the present invention;

FIG. 8 is a diagram showing modeling reflectivities of a second DBR in optical paths with different numbers of pairs of semiconductor layers according to the fourth preferable embodiment of the present invention;

FIG. 9 is a cross-sectional view of a fifth preferable embodiment of the present invention;

FIG. 10 is a diagram showing modeling reflectivities of a second DBR in optical paths with different numbers of pairs of semiconductor layers according to the fifth preferable embodiment of the present invention;

FIG. 11 is a cross-sectional view of a sixth preferable embodiment of the present invention;

FIG. 12 is a top view of the sixth preferable embodiment of the present invention;

FIG. 13 is a diagram showing modeling reflectivities of a second DBR in optical paths with different numbers of pairs of semiconductor layers according to the sixth preferable embodiment of the present invention; and

FIG. 14 is a cross-sectional view of a seventh preferable embodiment of the present invention.

### DETAILED DESCRIPTION OF THE PREFERRED EMBODIMENTS

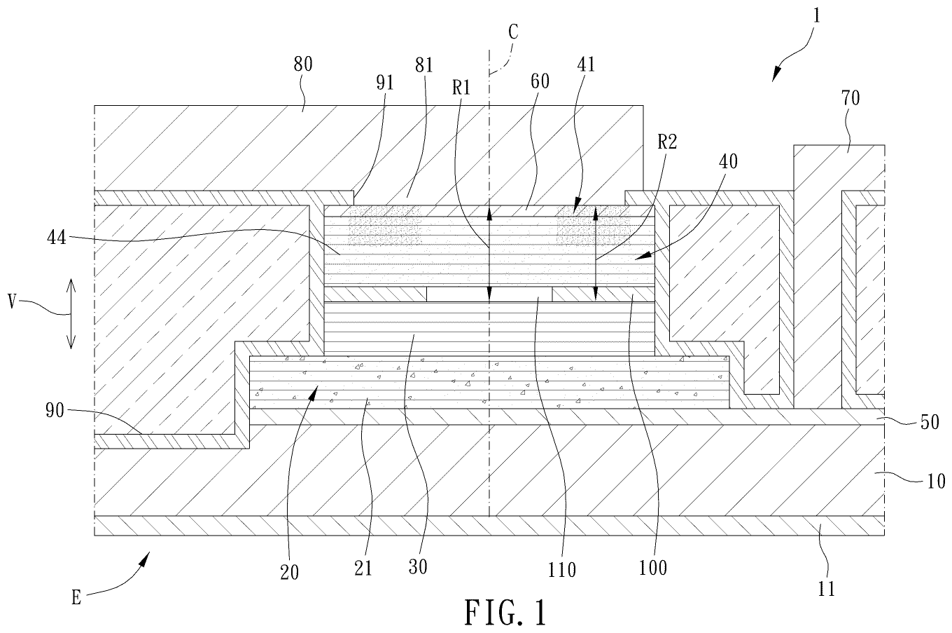

Please refer to FIGS. 1 to 3 for a first preferable embodiment of the present invention. A semiconductor light-emitting element 1 of the present invention includes a substrate 10, a first distributed Bragg reflector (DBR) 20, an active layer 30, a second DBR 40, a first contact layer 50, a second contact layer 60, a first metal layer 70 and a second metal layer 80.

The substrate 10 defines a thickness direction V. The first DBR 20 is disposed on a side of the substrate 10 in the thickness direction V and includes a plurality of pairs of semiconductor layers 21. The active layer 30 is disposed on a side of the first DBR 20 opposite to the substrate 10. The second DBR 40 is disposed on a side of the active layer 30 opposite to the first DBR 20 in the thickness direction V, and the second DBR 40 includes a plurality of pairs of semiconductor layers 44. A reflectivity of the second DBR 40 is greater than a reflectivity of the first DBR 20. The first contact layer 50 is disposed between the substrate 10 and the first DBR 20. The second contact layer 60 is disposed on a side of the second DBR 40 opposite to the active layer 30 in the thickness direction V. The first metal layer 70 is electrically connected with the first contact layer 50, and the second metal layer 80 is electrically connected with the second contact layer 60. A light emitting side E of the semiconductor light-emitting element 1 is located at a side of the substrate 10 remote from the first DBR 20. The first contact layer 50, the first DBR 20, the active layer 30, the second DBR 40 and the second contact layer 60 are stacked layer by layer in the thickness direction V to form a columnar structure P, and the columnar structure P defines a central axis C. The semiconductor light-emitting element 1 further includes an insulating layer 90 at least partially covered on an outer surface of the columnar structure P. The insulating layer 90 defines an embedding groove 91 open in the thickness direction V, and a connecting portion 81 of the second metal layer 80 is embedded within the embedding groove 91 and connected with the second contact layer 60. The plurality of pairs of semiconductor layers 21, 44 includes alternating layers of high refractive index and low refractive index. Therefore, the semiconductor light-emitting element 1 is a back-emitting lighting element, and the columnar structure P provides different reflectivities to reduce modes and stabilize polarization of the semiconductor light-emitting element 1.

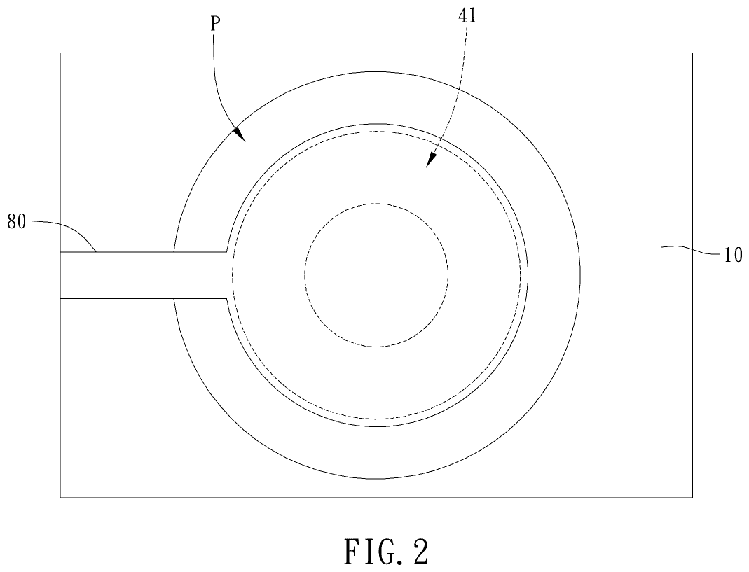

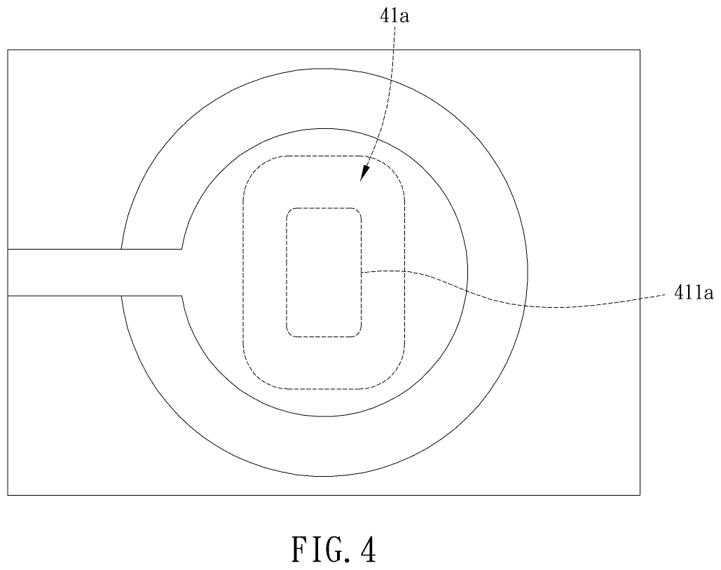

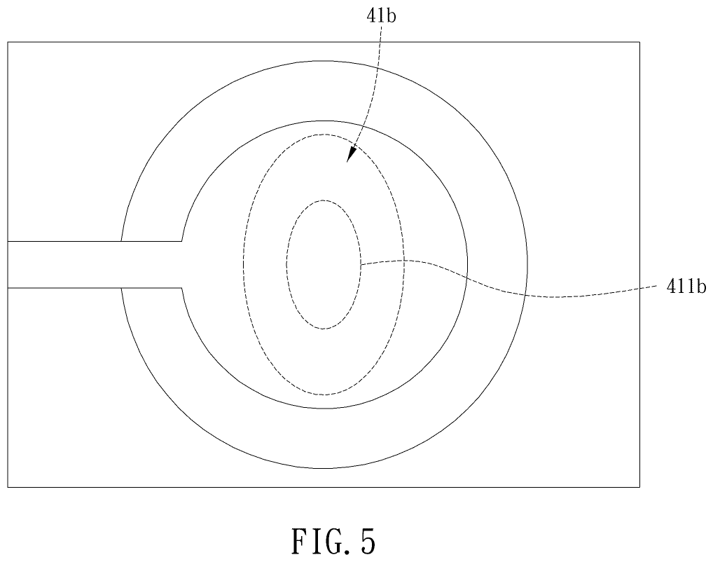

Specifically, the second DBR 40 further includes a metal diffusion layer 41, and the metal diffusion layer 41 is located at a side of at least one of the second contact layer 60 and the plurality of pairs of semiconductor layers 44 close to the second metal layer 80. The metal diffusion layer 41 extends and diffuses in a direction remote from the second metal layer 80. Specifically, the metal diffusion layer 41 is formed of a plurality of metal particles from the second metal layer 80 by the metal diffusion mechanism, and the plurality of metal particles diffuse from the second metal layer 80 toward at least one of the second contact layer 60 and the plurality of pairs of semiconductor layers 44. Therefore, a rough interface is formed between the second metal layer 80 and at least one of the second contact layer 60 and the plurality of pairs of semiconductor layers 44, and the rough interface and the metal diffusion layer 41 cause light scattering and absorption loss. An outer contour of the metal diffusion layer 41 at least partially corresponds to a shape of the connecting portion 81. In this embodiment, the metal diffusion layer 41 extends hollowly around the central axis C, as shown in FIG. 2, the metal diffusion layer 41 extends in a ring shape around the central axis C, a depth of the metal diffusion layer 41 in the thickness direction V is between 0.3 μm and 3 μm, and an inner contour of the metal diffusion layer 41 has a diametrical dimension between 2 μm and 15 μm. Therefore, an area of the second DBR 40 with the metal diffusion layer 41 has a lower resistance to guide an electric current to flow in a path close to the central axis C. Moreover, the metal diffusion layer 41 includes at least one metallic element including at least one of zinc, beryllium, germanium and tin, and a density of distribution of the at least one metallic element is preferably gradually decreased in a direction remote from the second metal layer 80 so that a reflectivity of an area of the columnar structure P adjacent to the central axis C is higher than a reflectivity of an area of the columnar structure P remote from the central axis C. In other embodiments, the metal diffusion layer may extend in a hollow rectangular or a hollow elliptical shape to meet different requirements. For example, when the metal diffusion layer 41a extends in a hollow rectangular shape, as shown in FIG. 4, a length of a hollow portion 411a defined by the metal diffusion layer 41a is between 2 μm and 15 μm, and a width of the hollow portion 411a is between 2 μm and 10 μm. When the metal diffusion layer 41b extends in a hollow elliptical shape, as shown in FIG. 5, a major axis of a hollow portion 411b defined by the metal diffusion layer 41b has a length between 2 μm and 15 μm, and a minor axis of the hollow portion 411b has a length between 2 μm and 10 μm.

The semiconductor light-emitting element 1 further includes an oxide-confined structure 100, the oxide-confined structure 100 includes an oxide aperture 110, and a center of the oxide aperture 110 is aligned with the central axis C so as to restrict a path of at least a part of a light generated by the active layer 30, increase resonance effect and facilitate suppression of modes. In this embodiment, the columnar structure P is cylindrical, the oxide-confined structure 100 includes an aluminum oxide layer with the oxide aperture 110 disposed thereon, and a diameter of the oxide aperture 110 is between 5 μm and 15 μm. The aluminum oxide layer has low refractive index, which effectively limits the light and the electrical current to the oxide aperture 110 to suppress modes and reduce thermal effect. In other embodiments, the oxide-confined structure may be replaced by an ion-implanted structure.

In this embodiment, the embedding groove 91 is a circular groove with a center passed through the central axis C and corresponding to the oxide aperture 110. As viewed in the thickness direction V, an end surface of the insulating layer 90 facing toward the second metal layer 80 has an outer diametrical dimension between 20 μm and 60 μm, and a maximum diametrical dimension of the connecting portion 81 is larger than or equal to ½ of the outer diametrical dimension of the end surface so as to provide sufficient reflection area for good photon resonance effect. As viewed in the thickness direction V, an extension area of the embedding groove 91 and an extension area of the insulating layer 90 at an end surface of the columnar structure P having the second metal layer 80 are respectively larger than or equal to 10% of an area of the end surface so as to provide sufficient reflection area for good reflection modulate effect.

A first optical path R1 and a second optical path R2 are relatively defined as a path that the light emitted from the active layer 30 toward the second metal layer 80 and then reflected toward the light emitting side E along the thickness direction V. The first optical path R1 is close to the central axis C relative to the second optical path R2, and a reflectivity provided in the first optical path R1 is greater than a reflectivity provided in the second optical path R2. By changing materials and structural designs of the second DBR 40, the metal diffusion layer 41 and the insulating layer 90, the first and second optical paths R1, R2 provide different reflectivities, which allows an area of the semiconductor light-emitting element 1 adjacent to the central axis C to provide preferable resonance effect relative to an area of the semiconductor light-emitting element 1 remote from the central axis C. Moreover, the light is transmitted in a path close to the central axis C so that the light emitted from the light emitting side E has order modes, which can be used to increase the bandwidth or transmission distance of lasers for optical communications, and can also be used to reduce a light divergence angle of radars for sensing.

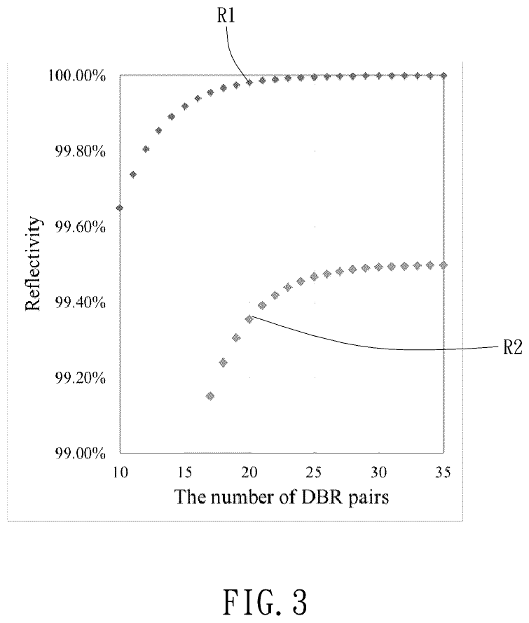

In this embodiment, the first optical path R1 is a path that the light emitted from the active layer 30 toward the second metal layer 80 and then reflected toward the light emitting side E; and the second optical path R2 is a path that the light emitted from the active layer 30 toward the second metal layer 80 through the metal diffusion layer 41 and then reflected toward the light emitting side E. Refer to FIG. 3 (each reflectivity is obtained by computer modeling), when the number of pairs of semiconductor layers 44 is unchanged (take 20 pairs as an example), the reflectivity of the light in the first optical path R1 is 99.98%, which is attributed to the material properties (high reflectivity) of the second metal layer 80. In the second optical path R2, the metal diffusion layer 41 provides light scattering effect, and the reflectivity of the light in the second optical path R2 is 99.35%, which is lower than the reflectivity of the light in the first optical path R1. Therefore, the area of the columnar structure P adjacent to the central axis C has better resonance effect relative to the area of the columnar structure P radially remote form the central axis C, which effectively reduces optical modes, and is easy to process and reliable.

Furthermore, the active layer 30 is made of a material including at least one of gallium arsenide (GaAs), aluminum gallium arsenide (AlGaAs), gallium indium arsenide (GaInAs), aluminum gallium indium arsenide (AlGaInAs), gallium indium phosphide (GaInP) and aluminum gallium indium phosphide (AlGaInP). A lattice constant mismatch between the material of the active layer 30 and gallium arsenide is smaller than 3%, the material of the active layer 30 may be doped with a p-type or n-type dopant or be undoped, and a doping concentration of the material of the active layer 30 is between 1.0×10¹⁵ cm⁻³ and 4.0×10¹⁸ cm⁻³. The first DBR 20 and the second DBR 40 are formed by alternating high and low refractive index layers. The first DBR 20 provides reflectivity of more than 95% at the emitting wavelength of the semiconductor light-emitting element 1, and the second DBR 40 provides reflectivity of more than 99% at the emitting wavelength of the semiconductor light-emitting element 1. The first DBR 20 and the second DBR 40 are respectively made of materials including at least one of gallium arsenide (GaAs), aluminum gallium arsenide (AlGaAs), gallium indium arsenide (GaInAs), aluminum gallium indium arsenide (AlGaInAs), gallium indium phosphide (GaInP) and aluminum gallium indium phosphide (AlGaInP). A lattice constant mismatch between said material of the first DBR 20 and gallium arsenide and a lattice constant mismatch between said material of the second DBR 40 and gallium arsenide are respectively smaller than 0.5%. The materials of the first DBR 20 and the second DBR 40 may be doped with a p-type or n-type dopant, and doping concentrations of the materials of the first DBR 20 and the second DBR 40 are respectively between 2.0×10¹⁷ cm⁻³ and 2.0×10¹⁹ cm⁻³. The first contact layer 50 and the second contact layer 60 are served as contact metals to form ohmic contact and are respectively made of materials including at least one of gallium arsenide (GaAs), aluminum gallium arsenide (AlGaAs), gallium indium arsenide (GaInAs), aluminum gallium indium arsenide (AlGaInAs), gallium indium phosphide (GaInP) and aluminum gallium indium phosphide (AlGaInP). A lattice constant mismatch between said material of the first contact layer 50 and gallium arsenide and a lattice constant mismatch between said material of the second contact layer 60 and gallium arsenide are respectively smaller than 0.5%. The first contact layer 50 is heavily doped with an n-type dopant, the second contact layer 60 is heavily doped with a p-type or n-type dopant, and doping concentrations of the first contact layer 50 and the second contact layer 60 are respectively between 3.0×10¹⁸ cm⁻³ and 2.0×10²⁰ cm⁻³.

Specifically, the columnar structure P is completely disposed on the substrate 10, and a side of the substrate 10 remote from the columnar structure P has an anti-reflective optical film 11, which is conducive to the emission of the light. In this embodiment, a wavelength of a light emitted from the light emitting side E is between 900 nm and 1200 nm. The substrate 10 is a semi-insulating, n-type or p-type doped board made of gallium arsenide (GaAs), and a thickness of the substrate 10 is between 50 μm and 800 μm.

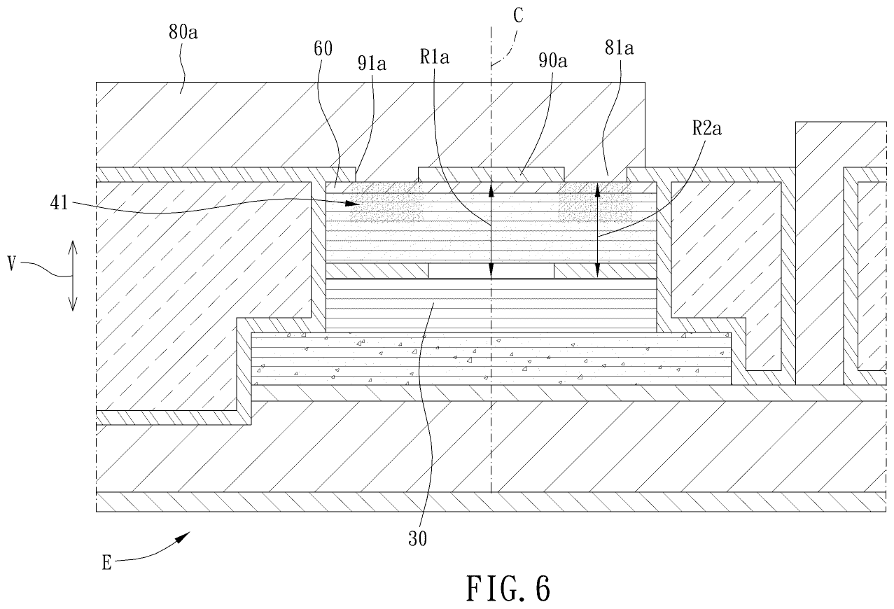

Please refer to a fourth preferable embodiment shown in FIGS. 6 to 8, which is different from the first preferable embodiment as described above in that: the connecting portion 81a has a hollow annular cross section, and a shape of the embedding groove 91a corresponds to a shape of the connecting portion 81a. The metal diffusion layer 41 and the embedding groove 91a correspond to each other in the thickness direction V. The first optical path R1a is a path that the light emitted from the active layer 30 toward the insulating layer 90a and then reflected toward the light emitting side E, and the second optical path R2a is a path that the light emitted from the active layer 30 toward the connecting portion 81a through the metal diffusion layer 41 and then reflected toward the light emitting side E. The metal diffusion layer 41 causes light scattering and optical loss so that the reflectivity of the light in the second optical path R2a is lower than the reflectivity of the light in the first optical path R1a. Moreover, at least a portion of the insulating layer 90a extends between the second metal layer 80a and the second contact layer 60, and the insulating layer 90a has a refractive index between 1.5 and 2.0 (such as 1.8 in this embodiment). In the thickness direction V, a thickness of the insulating layer 90a is between 250 nm and 300 nm (such as 272 nm in this embodiment) so as to form a high reflection layer and increase the reflectivity of the light in the first optical path R1a. In this embodiment, the insulating layer 90a is made of a material including at least one of silicon oxide, silicon nitride, aluminum oxide, titanium oxide, magnesium fluoride, tantalum oxide and indium tin oxide, and a portion of the insulating layer 90a extending between the second metal layer 80a and the second contact layer 60 has a thickness between 10 nm and 1000 nm. In other embodiments, a thickness and material of the insulating layer may be changed to meet expected reflection effect.

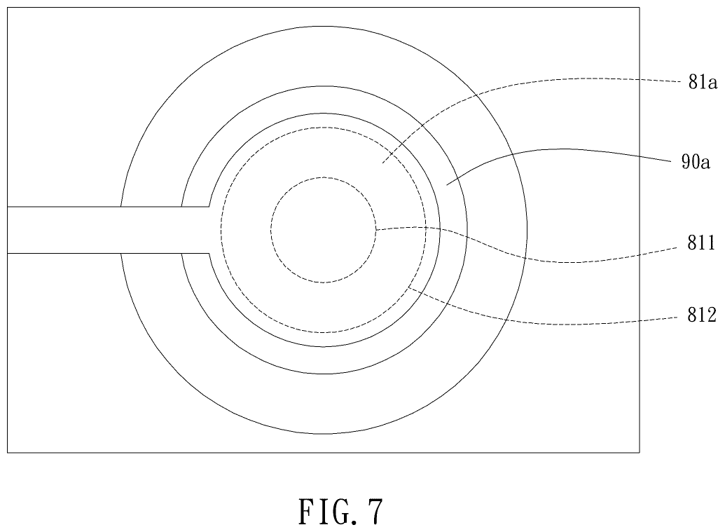

Please refer to FIG. 7, as viewed in the thickness direction V, the connecting portion 81a is ring-shaped, an inner contour 811 of the connecting portion 81a and an outer contour 812 of the connecting portion 81a are the same in shape and are concentric circles, and a diametrical dimension of the inner contour 811 is between 2 μm and 15 μm. However, shapes of the inner contour and the outer contour may be different, for example, the outer contour may be circular, and the inner contour may be elliptical, rectangular, polygonal or other shapes so as to control the polarization direction of the light.

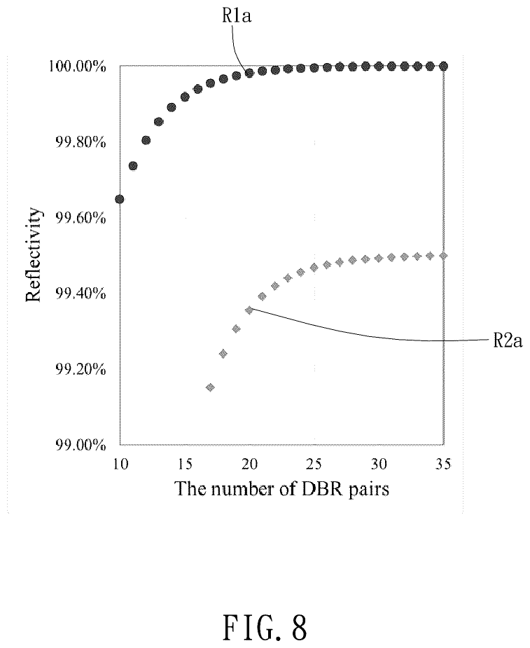

Please refer to FIG. 8, when the number of the plurality of pairs of semiconductor layers is unchanged (take 20 pairs as an example), the reflectivity of the light in the first optical path R1a is the highest (99.99%) due to the high reflectivity provided by the insulating layer 90a; the reflectivity of the light in the second optical path R2a (99.35%) is lower than the reflectivity of the light in the first optical path R1a due to the optical loss caused by the rough interface. Therefore, the area of the columnar structure P adjacent to the central axis C has better resonance effect relative to the area of the columnar structure P radially remote form the central axis C, which facilitates suppression of modes.

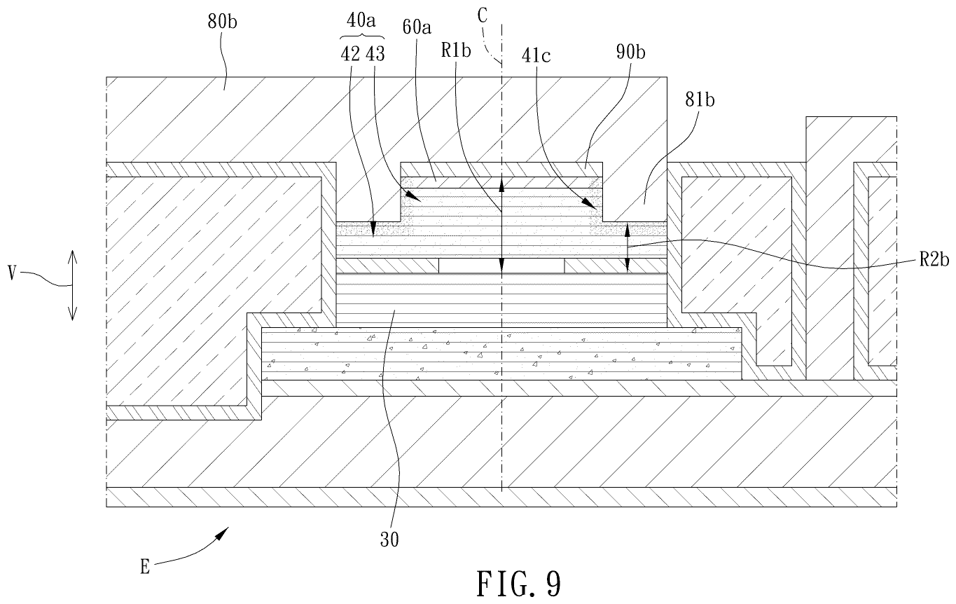

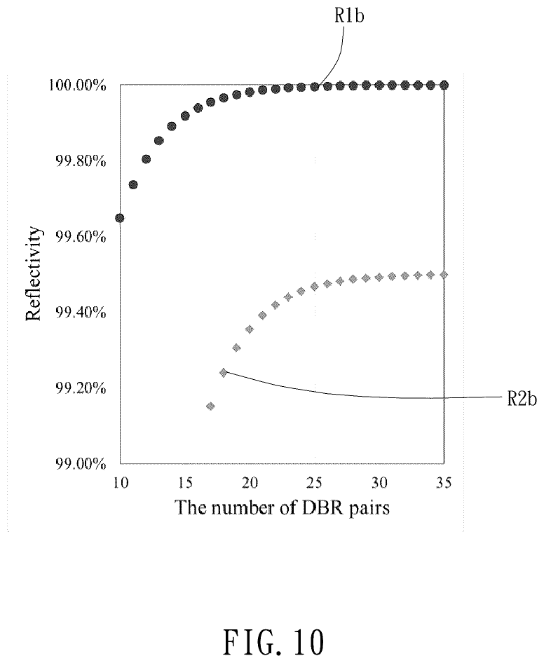

Please refer to a fifth preferable embodiment shown in FIGS. 9 and 10, which is different from the fourth preferable embodiment as described above in that: the second DBR 40a further includes a large diameter segment 42 close to the active layer 30 and a small diameter segment 43 close to the second contact layer 60a. A diametrical dimension of the large diameter segment 42 is larger than a diametrical dimension of the small diameter segment 43. The metal diffusion layer 41c is formed at outer peripheral sides of the small diameter segment 43 and the second contact layer 60a and a side of the large diameter segment 42 facing the second metal layer 80b. Preferably, a number of the plurality of pairs of semiconductor layers 44 located at the large diameter segment 42 is larger than a number of the plurality of pairs of semiconductor layers 44 located at the small diameter segment 43. For example, the large diameter segment 42 includes 18 pairs of semiconductor layers, and the small diameter segment 43 includes 7 pairs of semiconductor layers. As such, the area of the columnar structure P radially remote from the central axis C and the area of the columnar structure P adjacent to the central axis C respectively provide a path with a low reflectivity and a path with a high reflectivity, which directs the light to be emitted from an area adjacent to the central axis C and facilitates suppression of modes. In other embodiments, the number of said pairs of semiconductor layers in the large diameter segment may be less than the number of said pairs of semiconductor layers in the small diameter segment to meet different reflection requirements.

In this embodiment, as viewed in the thickness direction V, an outer contour of the large diameter segment 42 and an outer contour of the small diameter segment 43 are the same in shape and are concentric circles. A diametrical dimension of the large diameter segment 42 is between 20 μm and 60 μm, and a diametrical dimension of the small diameter segment 43 is between 2 μm and 15 μm. In other embodiments, the outer contour of the large diameter segment may have a different shape than the outer contour of the small diameter segment. For example, the outer contour of the large diameter segment may be circular, and the outer contour the small diameter segment may be elliptical, rectangular, polygonal or other shapes so as to control the polarization direction of the light.

The first optical path Rib is a path that the light emitted from the active layer 30 toward the insulating layer 90b and reflected toward the light emitting side E, and the second optical path R2b is a path that the light emitted from the active layer 30 toward a side of the connecting portion 81b facing the large diameter segment 42 and reflected toward the light emitting side E. Please refer to FIG. 10, in the first optical path Rib, the insulating layer 90b provides high reflectivity and the light passes through 25 pairs of semiconductor layers, and the reflectivity of the light in the first optical path Rib is 99.99%. In the second optical path R2b, the light passes 18 pairs of semiconductor layers and the metal diffusion layer 41c, and the reflectivity of the light in the second optical path R2b is 99.24%, which is lower than the reflectivity of the light in the first optical path Rib. Therefore, the reflectivity of the area of the columnar structure P remote from the central axis C is decreased, and the semiconductor light-emitting element 1 has a simple structure and is easy to be manufactured and accurately modulated.

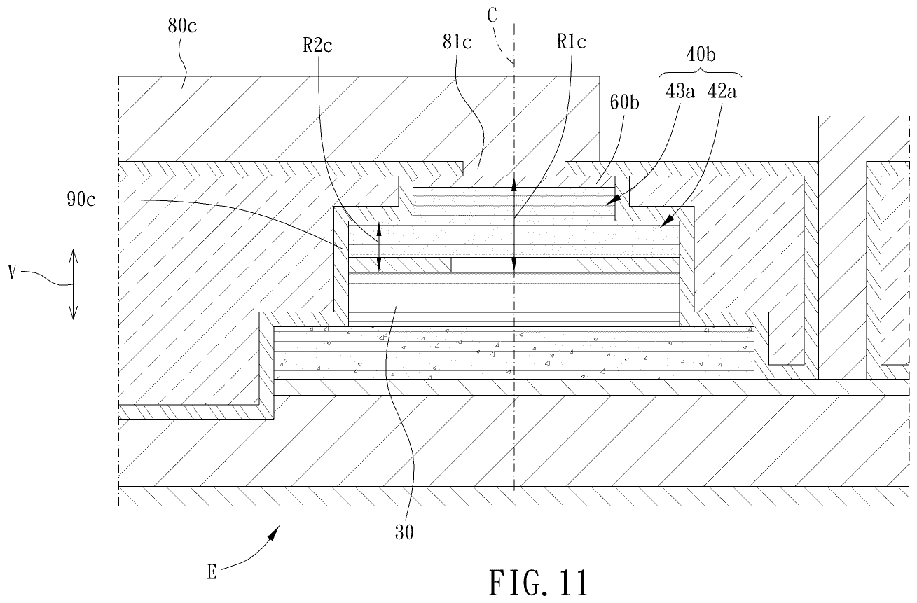

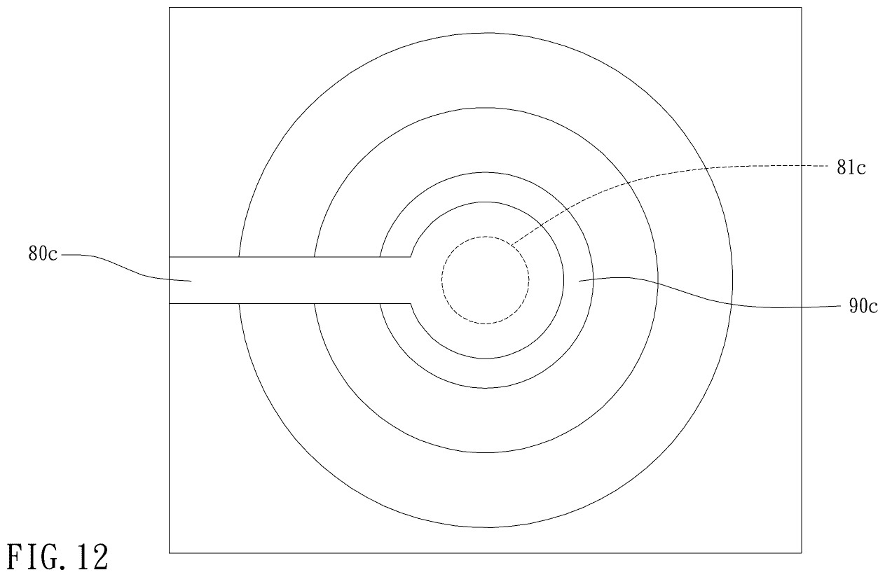

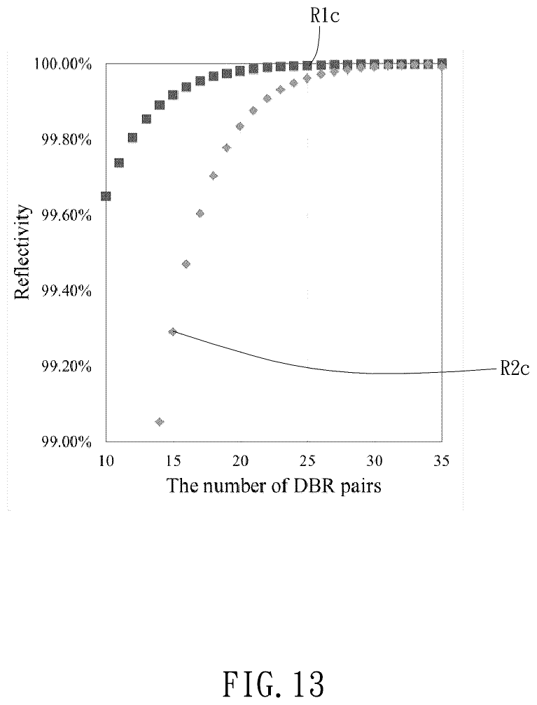

Please refer to a sixth preferable embodiment shown in FIGS. 11 to 13, which is different from the fifth preferable embodiment as described above in that: the second DBR 40b is not provided with the metal diffusion layer, the connecting portion 81c has a circular solid cross section, and the insulating layer 90c integrally covers the large diameter segment 42a, the small diameter segment 43a and the second contact layer 60b. In this embodiment, the large diameter segment 42a includes 15 pairs of semiconductor layers, and the small diameter segment 43a includes 10 pairs of semiconductor layers. The first optical path R1c is a path that the light emitted from the active layer 30 toward a side of the connecting portion 81c facing the second contact layer 60b and then reflected toward the light emitting side E, and the second optical path R2c is a path that the light emitted from the active layer 30 toward a side of the insulating layer 90c facing the large diameter segment 42a and then reflected toward the light emitting side E. In the first optical path R1c, the second metal layer 80c provides high reflectivity and the light passes through 25 pairs of semiconductor layers, the reflectivity of the light in the first optical path R1c is 99.98%. In the second optical path R2c, the light passes through 15 pairs of semiconductor layers, and the reflectivity of the light in the second optical path R2c is 99.29% which is lower than the reflectivity of the light in the first optical path R1c.

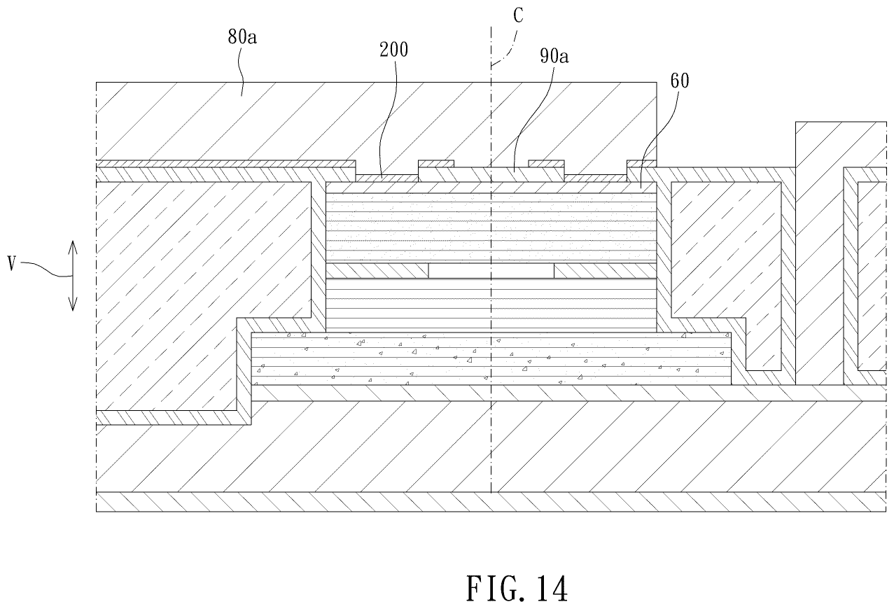

Please refer to a seventh preferable embodiment shown in FIG. 14, which is different from the fourth preferable embodiment as described above in that: the second metal layer 80a and one of the insulating layer 90a and the second contact layer 60 have a binding layer 200 disposed therebetween, and the binding layer 200 may be made of a material including at least one of titanium and zinc. Therefore, the second metal layer 80a can be stably connected with the insulating layer 90a and the second contact layer 60.

In summary, by changing the material or thickness of the insulating layer, the number of the plurality of DBR pairs, structures of the connecting portion and the embedding groove, distribution of the metal diffusion layer, etc., the semiconductor light-emitting element of the present invention provides optical paths with different reflectivities. The area of the columnar structure remote from the central axis provides an optical path with a low reflectivity, and the area of the columnar structure adjacent to the central axis provides an optical path with a high reflectivity. As such, the light has different resonance effect when transmitted in different areas, and the light is transmitted in an area close to the central axis, which is conducive to suppression of modes and the stabilization of polarization.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A semiconductor light-emitting element, including:
a substrate, defining a thickness direction;
a first distributed Bragg reflector (DBR), disposed on a side of the substrate in the thickness direction, including a plurality of pairs of semiconductor layers;
an active layer, disposed on a side of the first DBR opposite to the substrate;
a second DBR, disposed on a side of the active layer opposite to the first DBR in the thickness direction, including a plurality of pairs of semiconductor layers, a reflectivity of the second DBR being greater than a reflectivity of the first DBR;
a first contact layer, disposed between the substrate and the first DBR;
a second contact layer, disposed on a side of the second DBR opposite to the active layer in the thickness direction;
a first metal layer, electrically connected with the first contact layer; and
a second metal layer, electrically connected with the second contact layer;
wherein a light emitting side of the semiconductor light-emitting element is located at a side of the substrate remote from the first DBR; the first contact layer, the first DBR, the active layer, the second DBR and the second contact layer are stacked layer by layer in the thickness direction to form a columnar structure, the columnar structure defines a central axis, the semiconductor light-emitting element further includes an insulating layer at least partially covered on an outer surface of the columnar structure, the insulating layer defines an embedding groove open in the thickness direction, and a connecting portion of the second metal layer is embedded within the embedding groove and connected with the second contact layer;
wherein the second DBR further includes a metal diffusion layer, the metal diffusion layer is located at a side of at least one of the second contact layer and the plurality of pairs of semiconductor layers close to the second metal layer, and the metal diffusion layer extends and diffuses in a direction remote from the second metal layer.

2. The semiconductor light-emitting element of claim 1, wherein the connecting portion has a hollow annular cross section, and a shape of the embedding groove corresponds to a shape of the connecting portion.

3. The semiconductor light-emitting element of claim 2, wherein as viewed in the thickness direction, an inner contour of the connecting portion has the same shape as an outer contour of the connecting portion.

4. The semiconductor light-emitting element of claim 3, wherein the columnar structure is cylindrical, the connecting portion is ring-shaped; as viewed in the thickness direction, an end surface of the insulating layer facing toward the second metal layer has an outer diametrical dimension between 20 μm and 60 μm, and a diametrical dimension of the inner contour is between 2 μm and 15 μm.

5. The semiconductor light-emitting element of claim 1, wherein at least a portion of the insulating layer extends between the second metal layer and the second contact layer.

6. The semiconductor light-emitting element of claim 1, wherein a wavelength of a light emitted from the light emitting side is between 900 nm and 1200 nm.

7. The semiconductor light-emitting element of claim 1, further including an oxide-confined structure, wherein the columnar structure is cylindrical, the oxide-confined structure includes an oxide aperture, and a center of the oxide aperture is aligned with the central axis.

8. The semiconductor light-emitting element of claim 1, wherein as viewed in the thickness direction, an extension area of the embedding groove and an extension area of the insulating layer at an end surface of the columnar structure having the second metal layer are respectively larger than or equal to 10% of an area of the end surface.

9. The semiconductor light-emitting element of claim 1, wherein the substrate is a semi-insulating, n-type or p-type doped board made of gallium arsenide (GaAs), and a thickness of the substrate is between 50 μm and 800 μm.

10. The semiconductor light-emitting element of claim 1, wherein the active layer is made of a material including at least one of gallium arsenide (GaAs), aluminum gallium arsenide (AlGaAs), gallium indium arsenide (GaInAs), aluminum gallium indium arsenide (AlGaInAs), gallium indium phosphide (GaInP) and aluminum gallium indium phosphide (AlGaInP), a lattice constant mismatch between the material of the active layer and gallium arsenide is smaller than 3%, and a doping concentration of the material of the active layer is between 1.0×10¹⁵ cm⁻³ and 4.0×10¹⁸ cm⁻³; the first DBR and the second DBR are respectively made of materials including at least one of gallium arsenide (GaAs), aluminum gallium arsenide (AlGaAs), gallium indium arsenide (GaInAs), aluminum gallium indium arsenide (AlGaInAs), gallium indium phosphide (GaInP) and aluminum gallium indium phosphide (AlGaInP), and a lattice constant mismatch between said material of the first DBR and gallium arsenide and a lattice constant mismatch between said material of the second DBR and gallium arsenide are respectively smaller than 0.5%, and doping concentrations of the materials of the first DBR and the second DBR are respectively between 2.0×10⁷ cm⁻³ and 2.0×10¹⁹ cm⁻³.

11. The semiconductor light-emitting element of claim 1, wherein the first contact layer and the second contact layer are respectively made of materials including at least one of gallium arsenide (GaAs), aluminum gallium arsenide (AlGaAs), gallium indium arsenide (GaInAs), aluminum gallium indium arsenide (AlGaInAs), gallium indium phosphide (GaInP) and aluminum gallium indium phosphide (AlGaInP), a lattice constant mismatch between said material of the first contact layer and gallium arsenide and a lattice constant mismatch between said material of the second contact layer and gallium arsenide are respectively smaller than 0.5%; the first contact layer is heavily doped with a n-type dopant, the second contact layer is heavily doped with a p-type or n-type dopant, and doping concentrations of the first contact layer and the second contact layer are respectively between 3.0×10¹⁸ cm⁻³ and 2.0×10²⁰ cm⁻³.

12. The semiconductor light-emitting element of claim 1, wherein the second metal layer and one of the insulating layer and the second contact layer have a binding layer disposed therebetween, and the binding layer is made of a material including at least one of titanium and zinc.

13. The semiconductor light-emitting element of claim 1, wherein the second DBR further includes a large diameter segment close to the active layer and a small diameter segment close to the second contact layer, and a diametrical dimension of the large diameter segment is larger than a diametrical dimension of the small diameter segment.

14. The semiconductor light-emitting element of claim 13, wherein as viewed in the thickness direction, an outer contour of the large diameter segment has the same shape as an outer contour of the small diameter segment.

15. The semiconductor light-emitting element of claim 13, wherein a number of the plurality of pairs of semiconductor layers located at the large diameter segment is larger than a number of the plurality of pairs of semiconductor layers located at the small diameter segment.

16. The semiconductor light-emitting element of claim 1, wherein as viewed in the thickness direction, an end surface of the insulating layer facing toward the second metal layer has an outer diametrical dimension between 20 μm and 60 μm, and a maximum diametrical dimension of the connecting portion is larger than or equal to ½ of the outer diametrical dimension of the end surface.

17. The semiconductor light-emitting element of claim 1, wherein a shape of an outer contour of the metal diffusion layer at least partially corresponds to a shape of the connecting portion.

18. The semiconductor light-emitting element of claim 1, wherein the insulating layer is made of a material including at least one of silicon oxide, silicon nitride, aluminum oxide, titanium oxide, magnesium fluoride, tantalum oxide and indium tin oxide, and a portion of the insulating layer extending between the second metal layer and the second contact layer has a thickness between 10 nm and 1000 nm.

19. The semiconductor light-emitting element of claim 1, wherein the metal diffusion layer includes at least one metallic element including at least one of zinc, beryllium, germanium and tin.

20. The semiconductor light-emitting element of claim 1, wherein the metal diffusion layer extends hollowly around the central axis, and a depth of the metal diffusion layer in the thickness direction is between 0.3 μm and 3 μm.
